(19) United States
(12) Patent Application Publication
(10) Pub. No.: US 2026/0086130 A1
(43) Pub. Date: Mar. 26, 2026

(54) PATTERNED RESISTANCE DETECTION CIRCUIT AND METHOD FOR DETECTING PATTERNED RESISTANCE OF DISPLAY PANEL

(71) Applicant: LX SEMICON CO.,LTD., Daejeon (KR)

(72) Inventors: Dong Hwan KIM, Daejeon (KR); Sang Hun KIM, Daejeon (KR); Dean Yuan HUANG, Daejeon (KR)

(73) Assignee: LX SEMICON CO.,LTD., Daejeon (KR)

(21) Appl. No.: 19/108,034

(22) PCT Filed: Aug. 31, 2023
(86) PCT No.: PCT/KR2023/012959

§ 371 Date: Feb. 28, 2025

(30) Foreign Application Priority Data
Sep. 2, 2022 (KR) 10-2022-0111471

(51) Int. Cl. G01R 19/165; G09G 3/3233

(52) U.S. Cl. CPC G01R 19/16571; G09G 3/3233; G09G 2330/028; G09G 2330/04

(57) ABSTRACT

A patterned resistance detection circuit according to an aspect of the present invention comprises: a current source generator which generates a reference current and applies same to a patterned resistance; a reference voltage generator which generates a reference voltage by using a plurality of resistors and a plurality of switches; a comparator which compares the magnitude of a detection voltage detected by the reference current applied to the patterned resistance with the magnitude of the reference voltage and outputs a voltage comparison result; and a circuit controller which outputs a reference voltage control signal for controlling the plurality of switches according to the voltage comparison result.

### TECHNICAL FIELD

The present invention relates to a patterned resistance detection circuit and a patterned resistance detection method of a display panel.

### BACKGROUND ART

As the information society develops, demands for display device for displaying images are increasing in various forms, and recently, a variety of display devices such as LCD (Liquid Crystal Display Device), OLED (Organic Light Emitting Display Device) and the like are being utilized.

In a display device, a fault may occur as the resistance of a display panel increases or decreases due to the occurrence of damage to the internal circuit of the display panel or cracks in the display panel.

### DISCLOSURE

### Technical Problem

In order to solve the above problems, an objective of the present invention is to provide a patterned resistance detection circuit capable of detecting resistance of a display panel and a patterned resistance detection method of the display panel.

In addition, another technical objective of the present invention is to provide a patterned resistance detection circuit and a patterned resistance detection method of the display panel capable of improving resistance detection accuracy.

### Technical Solution

According to an aspect of the present invention for achieving the above objectives, a pattern resistor detection circuit includes: a current source generator configured to generate a reference current and applying the reference current to a patterned resistance; a reference voltage generator configured to generate a reference voltage using a plurality of resistors and a plurality of switches; a comparator configured to compare a magnitude of a detection voltage detected by the reference current applied to the patterned resistance with a magnitude of the reference voltage and outputting a voltage comparison result; and a circuit controller configured to output a reference voltage control signal for controlling the plurality of switches according to the voltage comparison result.

According to an aspect of the present invention for achieving the above objectives, a pattern resistor detection method circuit of a display panel includes: generating a reference current and applying the reference current to a patterned resistance of the display panel; comparing a magnitude of a detection voltage detected by the reference current applied to the patterned resistance and a magnitude of a reference voltage; when the number of comparisons between the reference voltage and the detection voltage is less than a predetermined value, changing the reference voltage based on the voltage comparison result between the detection voltage and the reference voltage, and comparing the changed reference voltage and the detection voltage; and when the number of comparisons between the reference voltage and the detection voltage is greater than or equal to the predetermined value, completing the detection of the patterned resistance.

### Effect of the Invention

According to the invention, the internal resistor and the variable switch occupying a large area may be removed by using a reference current instead of the variable resistance value. Accordingly, the present invention may reduce a circuit area.

In addition, the present invention may use a reference current and a reference voltage having a very small degree of change due to temperature, thereby maintaining high detection accuracy even when the temperature changes.

In addition, the present invention may improve detection accuracy by preventing current distortion due to channel length modulation.

### BRIEF DESCRIPTION OF THE DRAWINGS

FIG. 1 is a block diagram illustrating a display device according to one embodiment of the present invention.

FIG. 2 is a diagram illustrating a connection relationship between a display panel and a patterned resistance detection circuit according to one embodiment of the present invention.

FIG. 3 is a block diagram illustrating a configuration of a patterned resistance detection circuit according to one embodiment of the present invention.

FIG. 4 is a circuit diagram illustrating a configuration of the current source generator illustrated in FIG. 3.

FIG. 5 is a diagram for describing a channel length modulation phenomenon.

FIG. 6 is a block diagram schematically illustrating a configuration of the reference voltage generator shown in FIG. 3.

FIG. 7 is a circuit diagram illustrating an example of a digital-analog converter.

FIG. 8 is a flowchart illustrating a patterned resistance detection method of a display panel according to one embodiment of the present invention.

FIG. 9 is a diagram illustrating an example of a process in which a patterned resistance is detected by a patterned resistance detection circuit.

### BEST MODE OF CARRYING OUT THE INVENTION

Throughout the specification, the same reference numerals refer to substantially the same components. In the following description, detailed descriptions of configurations and features known in the art may be omitted if they are not relevant to the core configuration of the present invention. Terms used in this specification should be understood as follows.

The advantages and features of the present invention, and methods of achieving them will be apparent from the embodiments described in detail below in conjunction with the accompanying drawings. However, the present invention is not limited to the following embodiments, but may be implemented in various different forms; rather, the present embodiments are provided to make the description of the present invention complete and to allow those skilled in the art to fully understand the scope of the present invention, and the present invention is defined only within the scope of the appended claims.

Identical reference numerals may designate identical components throughout the description. Further, in describing the present invention, detailed descriptions of known related technologies may be omitted if it is considered to unnecessarily obscure the gist of the present invention.

The terms such as “including,” “having,” “comprising,” or the like used herein are generally intended to allow other components to be added unless the terms are used with the term “only.” References to components of a singular noun include the plural of that noun, unless specifically stated otherwise.

When describing a temporal contextual relationship is described, for example, such as “after,” “following,” “next to,” or “before,” it may also include non-contiguous cases unless “immediately” or “directly” is used.

The first, the second, and so on are used to describe various components, but these components are not limited by these terms. These terms are used only to distinguish one component from another. Therefore, the first component referred to herein may also be a second component within the technical idea of the present invention.

It should be understood that the term “at least one” includes any combination that may be presented from one or more relevant items. For example, the meaning of “at least one of the first item, the second item, and the third item” may mean each of the first item, the second item, and the third item as well as any combination of items that may be presented from two or more of the first item, the second item, and the third item.

Each of the features of various embodiments of the present invention may be coupled or combined with one another in whole or in part, and may be technologically interlocked and operated in various ways, and each of the embodiments may be carried out independently or in conjunction with one another.

Hereinafter, embodiments of the present invention will be described in detail with reference to the accompanying drawings.

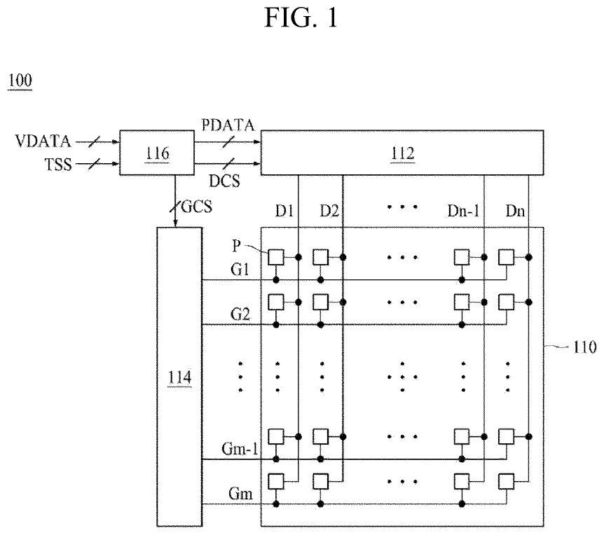

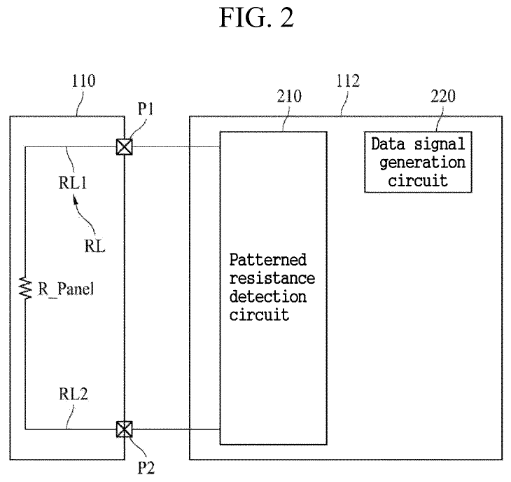

FIG. 1 is a block diagram illustrating a display device according to one embodiment of the present invention, and FIG. 2 is a diagram illustrating a connection relationship between a display panel and a patterned resistance detection circuit according to one embodiment of the present invention.

A display device 100, according to one embodiment of the present invention, may perform a display function and may be implemented as a flat panel display device, such as a Liquid Crystal Display (LCD) device or an Organic Light Emitting Diode (OLED) device.

Referring to FIG. 1, the display device 100 according to the present invention includes a display panel 110 and a display driver for driving the display panel 110.

The display panel 110 includes a display area, which is an area where a plurality of pixels P are arranged to display an image. The display panel 110 includes a plurality of data lines D1 to Dn, where n is a positive integer greater than or equal to 2, a plurality of gate lines G1 to Gm, where m is a positive integer greater than or equal to 2, and a plurality of pixels P.

Each of the plurality of data lines D1 to Dn receives a data signal. Each of the plurality of gate lines G1 to Gm receives a gate signal. A plurality of data lines D1 to Dn and a plurality of gate lines G1 to Gm are arranged to intersect each other on the substrate to define a plurality of pixels P. Each of the plurality of pixels P may be connected to any one of the plurality of data lines D1 to Dn and any one of the plurality of gate lines G1 to Gm. Each of the plurality of pixels P may include a driving transistor, a scan transistor that is turned on by a gate signal on a gate line to supply a data voltage from a data line to a gate electrode of the driving transistor, an organic light-emitting diode that emits light in response to a drain-source current of the driving transistor, and a capacitor for storing the voltage of the gate electrode of the driving transistor. Thus, each of the plurality of pixels P may emit light according to the current supplied to the organic light-emitting diode.

The display panel 110, according to one embodiment of the present invention, may include a patterned resistance circuit. The patterned resistance circuit may include a first pad P1, a patterned resistance R_Panel, a resistance line RL, and a second pad P2, as shown in FIG. 2.

The first pad P1 may be located at one end of the display panel 110 and may be connected to the patterned resistance detection circuit 210 of the data driver 112. The second pad P2 may be located at the other end of the display panel 110 and may be connected to the patterned resistance detection circuit 210 of the data driver 112. In FIG. 2, the first pad P1 and the second pad P2 are shown to be located at different corners, but are not necessarily limited thereto. The first pad P1 and the second pad P2 may be disposed to be spaced apart from one corner of the display panel 110.

The resistance line RL may be disposed along an edge of the display panel 110, which may electrically connect the patterned resistance R_Panel to the first pad P1 and the second pad P2. Specifically, the resistance line RL may include a first resistance line RL1 electrically connecting the patterned resistance R_Panel and the first pad P1 and a second resistance line RL2 electrically connecting the patterned resistance R_Panel and the second pad P2.

The patterned resistance R_Panel may be connected to the patterned resistance detection circuit 210 via the resistance line RL and the first and second pads P1 and P2. The magnitude of the patterned resistance R_Panel may be detected by the patterned resistance detection circuit 210.

The display driver ensures that data signals are supplied to a plurality of pixels P included in the display panel 110 to display an image on the display panel 110. To this end, the display driver may include a data driver 112, a gate driver 114, and a timing controller 116.

The timing controller 116 receives digital video data VDATA and timing signals TSS from the host system. The timing signals TSS may include a reference clock signal (e.g., a dot clock), a vertical synchronization signal, a horizontal synchronization signal, a data enable signal, and the like. The vertical synchronization signal is a signal that defines one frame period. The horizontal synchronization signal is a signal that defines one horizontal period required to supply data signals to the pixels P on one horizontal line of the display panel 110. The data enable signal is a signal that defines a period of time during which valid data is input. The dot clock is a signal that repeats at a predetermined short period.

The timing controller 116 may include a data processor (not shown) that utilizes the digital video data VDATA and the timing signals TSS to generate pixel data PDATA, data control signals DCS, and gate control signals GCS.

In order to control the operation timings of the data driver 112 and the gate driver 114, the data processor of the timing controller 116 may generate a data control signal DCS for controlling the operation timings of the data driver 112 and a gate control signal GCS for controlling the operation timings of the gate driver 114 based on the timing signals TSS.

Further, the data processor of the timing controller 116 may align the digital video data VDATA to match the pixel structure formed on the display panel 105 and convert the aligned digital video data VDATA into the pixel data PDATA. For example, the data processor may convert and align digital video data VDATA for three colors red, green, and blue into pixel data PDATA for four colors white, red, green, and blue using a predetermined conversion method. Further, the data processor may correct the pixel data PDATA through various image processing such as image quality compensation, external compensation, and degradation compensation.

The gate driver 114 receives a gate control signal GCS from the timing controller 116. The gate driver 114 supplies gate signals to the plurality of gate lines G1 to Gm according to the gate control signal GCS.

Specifically, the gate driver 114 generates a gate signal (or a scan signal) synchronized with the data signal under the control of the timing controller 116, and sequentially supplies the generated gate signal to the gate lines G1 to Gm while shifting the generated gate signal. To this end, the gate driver 114 may include a plurality of gate drive ICs (not shown). The gate drive ICs may sequentially supply a gate signal synchronized with a data signal to the plurality of gate lines G1 to Gm under the control of the timing controller 116 to select a data line on which the data signal is written. The gate signal may swing between a gate high voltage and a gate low voltage.

The data driver 112 receives the pixel data PDATA and the data control signal DCS from the timing controller 116. As shown in FIG. 2, the data driver 112 according to one embodiment of the present invention is characterized in that it includes the patterned resistance detection circuit 210 and a data signal generation circuit 220.

The data signal generation circuit 220 converts the pixel data PDATA of a digital form of into analog positive/negative data signals according to the data control signal DCS and supplies the analog positive/negative data signals to the pixels P via the plurality of data lines D1 to Dn.

The patterned resistance detection circuit 210 is connected to the patterned resistance circuit of a specific device to detect the patterned resistance R_Panel of the patterned resistance circuit. The specific device may refer to a device including a patterned resistance circuit. In the following, the device is described as the display panel 110, but is not necessarily limited thereto.

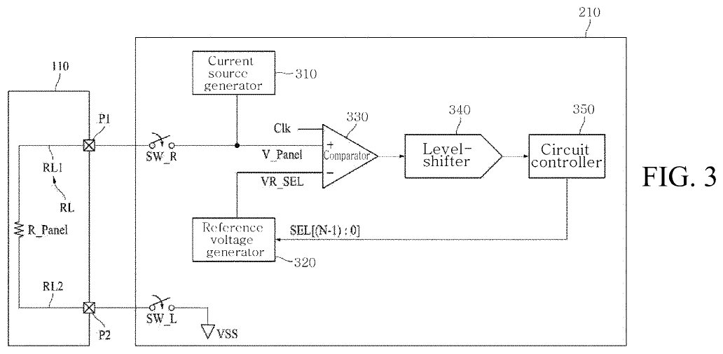

In the following, the patterned resistance detection circuit 210 will be described in detail with reference to FIGS. 3 to 7.

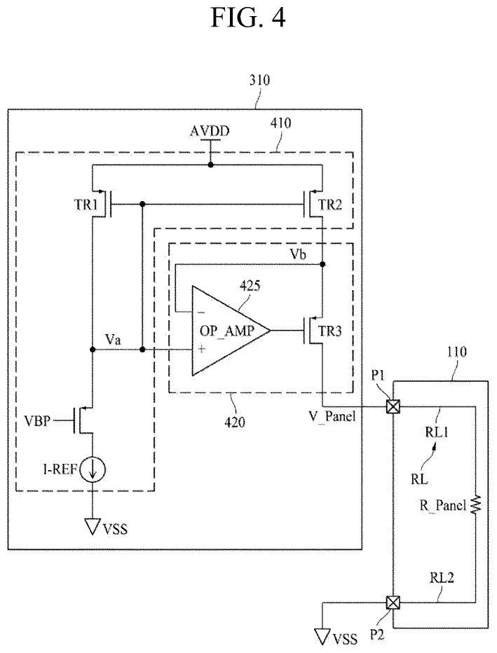

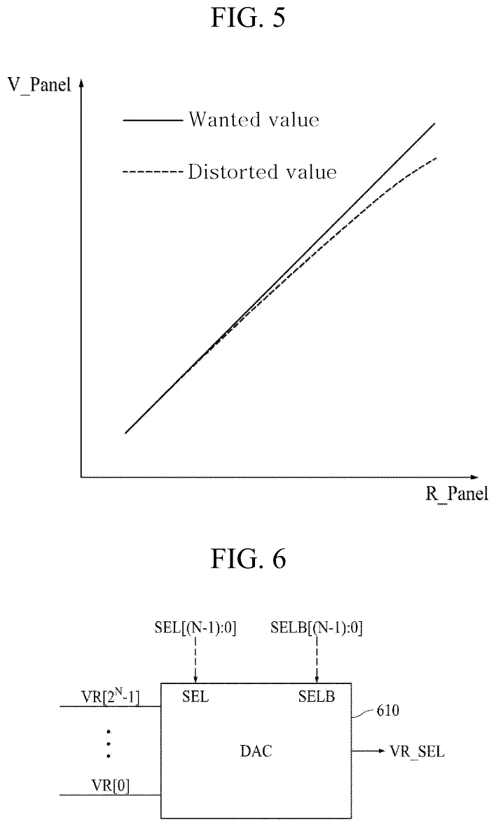

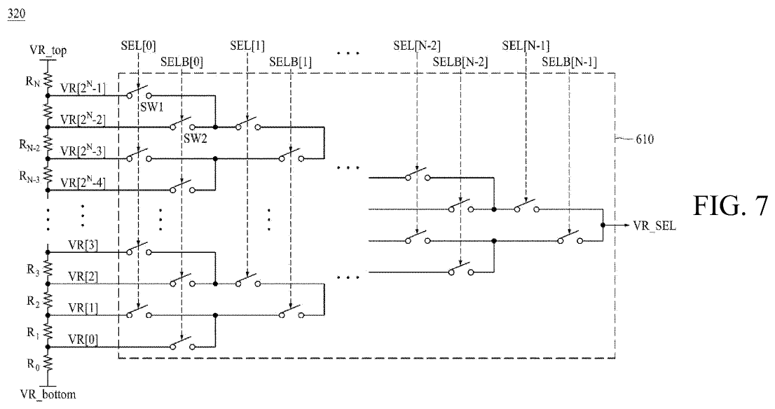

FIG. 3 is a block diagram illustrating a configuration of the patterned resistance detection circuit according to one embodiment of the present invention, FIG. 4 is a circuit diagram illustrating a configuration of the current source generator illustrated in FIG. 3, and FIG. 5 is a diagram for describing a channel length modulation phenomenon. FIG. 6 is a block diagram schematically illustrating a configuration of the reference voltage generator shown in FIG. 3, and FIG. 7 is a circuit diagram illustrating an example of a digital-analog converter.

The patterned resistance detection circuit 210 detects the magnitude of the detected resistance. The patterned resistance detection circuit 210 according to one embodiment of the present invention may be connected to the patterned resistance circuit of the display panel 110 to detect the magnitude of the patterned resistance R_Panel of the patterned resistance circuit. According to one embodiment of the present invention, the magnitude of the patterned resistance R_Panel detected through the patterned resistance detection circuit 210 may be used to determine whether the display panel 110 is fault.

Referring to FIG. 3, the patterned resistance detection circuit 210 includes a current source generator 310, a reference voltage generator 320, a comparator 330, and a circuit controller 350. In one embodiment, the patterned resistance detection circuit 210 may further include a level shifter 340.

The current source generator 310 generates a reference current and applies the generated reference current to the patterned resistance R_Panel via the first pad P1 of the display panel 110. As illustrated in FIG. 4, the current source generator 310 may include a reference current generation circuit 410 to generate the reference current.

The reference current generation circuit 410 may include a current source I_REF, a first transistor TR1, and a second transistor TR2. In one embodiment, the first transistor TR1 and the second transistor TR2 may be MOS transistors.

The current source I_REF may be connected to a first power source VSS. The first transistor TR1 may be connected to the current source I_REF and a second power source VDD to allow the first reference current to flow therethrough. Here, the first power source VSS may be a low potential voltage or ground voltage, and the second power source VDD may be a high potential voltage.

Specifically, the first transistor TR1 may include a first gate electrode, a first drain electrode, and a first source electrode. The first drain electrode of the first transistor TR1 is connected to the current source I_REF, and the first source electrode of the first transistor TR1 is connected to the second power source VDD, so that a first reference current may flow between the first drain electrode and the first source electrode. The first drain electrode of the first transistor TR1 may be connected to the first gate electrode of the first transistor TR1, and accordingly, the first drain voltage and the first gate voltage may be the same.

The second transistor TR2 may be connected to the first transistor TR1 so that a second reference current obtained by copying the first reference current flowing through the first transistor TR1 may flow.

Specifically, the second transistor TR2 may include a second gate electrode, a second drain electrode, and a second source electrode. The second drain electrode of the second transistor TR2 may be connected to the patterned resistance R_Panel of the display panel 110, and the second source electrode of the second transistor TR2 may be connected to the second power source VDD. The second gate electrode of the second transistor TR2 may be connected to the first gate electrode of the first transistor TR1. Accordingly, the first reference current flowing through the first transistor TR1 may be copied, and thus a second reference current may flow between the second drain electrode and the second source electrode of the second transistor TR2.

The first pad P1 of the display panel 110 may be connected to the reference current generation circuit 410, in particular, the second transistor TR2, and the second pad P2 of the display panel 110 may be connected to the first power source VSS. Accordingly, the second reference current flowing through the second transistor TR2 may be applied to the patterned resistance R_Panel via the first pad P1 of the display panel 110.

In one embodiment, a first switch SW_R may be provided between the current source generator 310 and the first pad P1 of the display panel 110. In this case, when the first switch SW_R is turned on by a patterned resistance detection operation signal, the current source generator 310 is connected to the first pad P1 of the display panel 110 and may apply the reference current to the patterned resistance R_Panel via the first pad P1 of the display panel 110.

In one embodiment, a second switch SW_L may be further provided between the second pad P2 of the display panel 110 and the first power source VSS. The second switch SW_L may be turned on together with the first switch SW_R by the patterned resistance detection operation signal.

In one embodiment, the reference current generation circuit 410 may further include a bias transistor VBP. The bias transistor VBP is provided between the current source I_REF and the first transistor TR1 to provide a constant bias current to the first transistor TR1.

Meanwhile, in the current source generator 310, even though the magnitude of the current source I_REF is fixed, the second reference current flowing through the second transistor TR2 may change due to a change in the patterned resistance R_Panel. To explain in detail with reference to FIG. 5, the patterned resistance R_Panel does not have a fixed value and may be changed to various values. As the patterned resistance R_Panel changes, the detection voltage V_Panel detected by the patterned resistance R_Panel also changes. Accordingly, the second drain voltage of the second transistor TR2 may be changed, and the second reference current flowing through the second transistor TR2 may be different from the first reference current flowing through the first transistor TR1.

As such, although the second source voltage and the second gate voltage of the second transistor TR2 are fixed, a phenomenon in which the magnitude of the second reference current flowing through the second transistor TR2 increases or decreases due to the increase or decrease of the second drain voltage is referred to as channel length modulation. When the second reference current applied from the second transistor TR2 to the patterned resistance R_Panel increases or decreases due to the channel length modulation, the actually detected detection voltage V_Panel is different from the wanted value as shown in FIG. 5, which may result in a decrease in the detection accuracy.

The current source generator 310 may further include a channel length modulation prevention circuit 420 to prevent current distortion due to the channel length modulation. The channel length modulation prevention circuit 420 may include a differential amplifier 425 and a third transistor TR3. In one embodiment, the third transistor TR3 may be a MOS transistor.

The differential amplifier 425 may amplify the difference between the first drain voltage Va of the first transistor TR1 and the second drain voltage Vb of the second transistor TR2. The differential amplifier 425 may include a non-inverting input terminal (+) connected to the first drain electrode of a first transistor TR1, an inverting input terminal (−) connected to the second drain electrode of a second transistor TR2, and an output terminal connected to a third gate electrode of the third transistor TR3.

The third transistor TR3 may include a third drain electrode connected to the patterned resistance R_Panel, the third gate electrode connected to the differential amplifier 425, and a third source electrode connected to the second drain electrode of the second transistor TR2.

The channel length modulation prevention circuit 420 may ensure that the second drain voltage Vb of the second transistor TR2 is fixed to the first drain voltage Va of the first transistor TR1 without being affected by a change in the patterned resistance R_Panel by using the differential amplifier 425 and the third transistor TR3. Thus, the patterned resistance detection circuit 210 according to one embodiment of the present invention may prevent current distortion due to channel length modulation.

The comparator 330 compares the magnitude of the detection voltage V_Panel detected by the reference current applied to the patterned resistance R_Panel with the magnitude of the reference voltage VR_SEL. The comparator 330 may include a non-inverting input terminal (+) to which the detection voltage V_Panel detected by the reference current applied to the patterned resistance R_Panel is input, an inverting input terminal (−) to which the reference voltage VR_SEL output from the reference voltage generator 320 is input, and an output terminal for outputting a voltage comparison result between the detection voltage V_Panel and the reference voltage VR_SEL.

When the detection voltage V_Panel is greater than the reference voltage VR_SEL, the comparator 330 may output a high-level signal as a result of a voltage comparison between the detection voltage V_Panel and the reference voltage VR_SEL. On the other hand, when the detection voltage V_Panel is less than the reference voltage VR_SEL, the comparator 330 may output a low-level signal as a voltage comparison result between the detection voltage V_Panel and the reference voltage VR_SEL.

In one embodiment, the comparator 330 may compare the magnitudes of the detection voltage V_Panel and the reference voltage VR_SEL based on a clock signal Clk. The clock signal Clk may be input from the timing controller 116.

The level shifter 340 may adjust the level of the voltage comparison result output from the comparator 330 and delivery it to the circuit controller 350.

The circuit controller 350 generates a reference voltage control signal based on the voltage comparison result and outputs the reference voltage control signal to the reference voltage generator 320. Specifically, the circuit controller 350 may select one of the plurality of voltages as a new reference voltage based on the voltage comparison result. The circuit controller 350 may generate a reference voltage control signal for generating the reference voltage to be selected and output the reference voltage control signal to the reference voltage generator 320.

In one embodiment, the circuit controller 350 may generate an N-bit reference voltage control signal SEL[(N−1):0] to generate one of 2^{N} voltages as the reference voltage.

Specifically, the circuit controller 350 may select one of the 2^{N} voltages as a new reference voltage based on the voltage comparison result. When the voltage comparison result is a high level, the circuit controller 350 may select one of the voltages greater than a current reference voltage from among the 2^{N} voltages as the new reference voltage VR_SEL. That is, when the detection voltage V_Panel is greater than the reference voltage VR_SEL, the circuit controller 350 may select a voltage greater than the current reference voltage from among the 2^{N} voltages as the new reference voltage.

In one embodiment, when the voltage comparison result is a high level, the circuit controller 350 may change the minimum voltage of the expected range to the current reference voltage and select one of the voltages between the maximum voltage of the expected range and the minimum voltage of the expected range from among the 2^{N} voltages as the new reference voltage. For example, the circuit controller 350 may select a voltage having a median value from among the voltages between the maximum voltage and the minimum voltage of the expected range as the new reference voltage.

On the other hand, when the voltage comparison result is a low level, the circuit controller 350 may select one of the 2^{N} voltages that is smaller than the current reference voltage as the new reference voltage. In other words, when the detection voltage V_Panel is less than the reference voltage VR_SEL, the circuit controller 350 may select a voltage smaller than the current reference voltage from among the 2^{N} voltages as the new reference voltage.

In one embodiment, when the voltage comparison result is a low level, the circuit controller 350 may change the maximum voltage of the expected range to the current reference voltage and select one of the voltages between the maximum voltage of the expected range and the minimum voltage of the expected range among the 2^{N} voltages as the new reference voltage. For example, the circuit controller 350 may select a voltage having a median value from among the voltages between the maximum voltage and the minimum voltage of the expected range as the new reference voltage.

In addition, the circuit controller 350 may generate an N-bit reference voltage control signal SEL[(N−1):0] for generating the selected reference voltage, and output the generated N-bit reference voltage control signal SEL[(N−1):0] to the reference voltage generator 320.

The N-bit reference voltage control signal SEL[(N−1):0] may contain 2^{N} reference voltage control signals having different values. The 2^{N} reference voltage control signals may correspond to 2^{N} voltages, respectively, and the 2^{N} voltages may correspond to the magnitudes of the 2^{N} patterned resistance R_Panel, respectively.

For example, the circuit controller 350 may generate a 4-bit reference voltage control signal (SEL[3:0]). In this case, the 4-bit reference voltage control signal SEL[3:0] may correspond to the magnitudes of 2^{N} patterned resistance R_Panel corresponding to the 2^{N} voltages, respectively, as shown in Table 1 below.

TABLE 1

| SEL[3:0] | R_Panel[kΩ] |
|---|---|
| 0000 | 1 |
| 0001 | 2 |
| 0010 | 3 |
| 0011 | 4 |
| 0100 | 5 |
| 0101 | 6 |
| 0110 | 7 |
| 0111 | 8 |
| 1000 | 9 |
| 1001 | 10 |
| 1010 | 11 |
| 1011 | 12 |
| 1100 | 13 |
| 1101 | 14 |
| 1110 | 15 |
| 1111 | 16 |

Referring to Table 1, for an example, the circuit controller 350 may select a voltage corresponding to the patterned resistance R_Panel having a magnitude of “9” from among 24 voltages as the reference voltage. The circuit controller 350 may generate “1000” as the reference voltage control signal SEL[3:0] in order to generate the selected reference voltage. The circuit controller 350 may output the reference voltage control signal SEL[3:0] of “1000” to the reference voltage generator 320. The reference voltage generator 320 may generate the reference voltage VR_SEL corresponding to the patterned resistance R_Panel having a magnitude of “9” according to the reference voltage control signal SEL[3:0] of “1000”, and the generated reference voltage VR_SEL may be output to the comparator 330.

When the detection voltage V_Panel is greater than the reference voltage VR_SEL, the circuit controller 350 may select one of the 24 voltages greater than the current reference voltage as the new reference voltage. When the voltage comparison result is a high level, the circuit controller unit 350 may select a voltage corresponding to the patterned resistance R_Panel having a magnitude of “13” from among the 24 voltages as a new reference voltage. The circuit controller 350 may generate “1100” as the reference voltage control signal SEL[3:0] in order to generate the selected reference voltage. The circuit controller 350 may output the reference voltage control signal SEL[3:0] of “1100” to the reference voltage generator 320. The reference voltage generator 320 may generate the reference voltage VR_SEL corresponding to the patterned resistor R_Panel having a magnitude of “13” according to the reference voltage control signal SEL[3:0] of “1100”, and the generated reference voltage VR_SEL may be output to the comparator 330.

In one embodiment, the circuit controller 350 may generate the N-bit reference voltage control signal SEL[(N−1):0] by changing the value of some bits of the N bits based on the voltage comparison result.

Specifically, when the detection voltage V_Panel is greater than the reference voltage VR_SEL, the circuit controller 350 may generate the reference voltage control signal SEL[(N−1):0] by maintaining the value of the bit of the (i−1)th digit of the most significant bit and changing the value of the bit of the (i)th digit from 0 to 1. Where i is the number of comparisons between the detection voltage V_Panel and the reference voltage VR_SEL.

For example, when the number of comparisons is 1 and the detection voltage V_Panel is greater than the reference voltage VR_SEL generated by the reference voltage control signal SEL[3:0] of “1000”, the circuit controller 350 may generate the reference voltage control signal SEL[3:0] of “1100”.

When the detection voltage V_Panel is less than the reference voltage VR_SEL, the circuit controller 350 may generate the reference voltage control signal SEL[(N−1):0] by changing the value of the bit of the (i−1)th digit of the most significant bit to 0 and changing the value of the bit of the (i)th digit from 0 to 1.

For example, when the number of comparisons is 1 and the detection voltage V_Panel is less than the reference voltage VR_SEL generated by the reference voltage control signal SEL[3:0] of “1000”, the circuit controller 350 may generate the reference voltage control signal SEL[3:0] of “0100”.

Meanwhile, the circuit controller 350 may stop the detection operation of the patterned resistance R_Panel when the number of comparisons between the detection voltage V_Panel and the reference voltage VR_SEL is greater than a preset value. The user may determine the patterned resistance R_Panel of the display panel 110 based on the finally selected reference voltage or the final reference voltage control signal SEL[(N−1):0]. Referring to Table 1, for example, when the reference voltage control signal SEL[(N−1):0] is “1011”, the user may determine that the magnitude of the patterned resistance R_Panel of the display panel 110 is 12.

In addition, the circuit controller 350 may determine a fault of the display panel 110 based on the finally selected reference voltage or the final reference voltage control signal SEL[(N−1):0]. For example, when the reference voltage control signal SEL[(N−1):0] is either “0000” or “1111”, the circuit controller 350 may determine that there is a fault in the display panel 110.

The reference voltage generator 320 generates a reference voltage VR_SEL under the control of the circuit controller 350, and outputs the generated reference voltage VR_SEL to the comparator 330.

Referring to FIGS. 6 and 7, the reference voltage generator 320 may include a digital-analog converter DAC 610 including a plurality of resistors R₀, R₁, . . . , R_{N-1} and R_{N} and a plurality of switches SW.

The plurality of resistors R₀, R₁, . . . , R_{N-1} and R_{N} may be connected in series between the first voltage VR_bottom and the second voltage VR_top. Here, the first voltage VR_bottom may correspond to the lowest voltage, and the second voltage VR_top may correspond to the highest voltage.

The first voltage VR_bottom and the second voltage VR_top may be determined based on the range of the reference current and the patterned resistance R_Panel. The range of the patterned resistance R_Panel may vary for each device. In one embodiment, the first voltage VR_bottom may correspond to a value obtained by multiplying the reference current by the minimum value of the patterned resistance R_Panel. The second voltage VR_top may correspond to a value obtained by multiplying the reference current by the maximum value of the patterned resistance R_Panel.

In one embodiment, the plurality of resistors R₀, R₁, . . . , R_{N-1} and R_{N} may have the same magnitude.

The DAC 610 receives a plurality of reference voltages VR[0], VR[1], . . . , VR[2^{N}−2], and VR[2^{N}−1] from the nodes between the plurality of resistors R₀, R₁, . . . , R_{N-1} and R_{N} and outputs one reference voltage VR_SEL selected from among the plurality of reference voltages VR[0], VR[1], . . . , VR[2^{N}−2], and VR[2^{N}−1] under control of the circuit controller 350.

To this end, the DAC 610 may include a plurality of switches SW connected to the nodes between the plurality of resistors R₀, R₁, . . . , R_{N-1} and R_{N}. In response to the reference voltage control signal SEL[(N−1):0] input from the circuit controller 350, the plurality of switches SW may be turned on or turned off, and thus one reference voltage VR_SEL from among the plurality of reference voltages VR[0], VR[1], . . . , VR[2^{N}-2], and VR[2^{N}−1] may be output from the DAC 610.

In one embodiment, the DAC 610 may receive 2^{N} reference voltages VR[0], VR[1], . . . , VR[2^{N}-2], and VR[2^{N}−1] from the nodes between the plurality of resistors R0, R₀, R₁, . . . , R_{N-1} and R_{N}. When an N-bit reference voltage control signal SEL[(N−1):0] is input from the circuit controller 350, the DAC 610 may control the plurality of switches SW according to the N-bit reference voltage control signal SEL[(N−1):0] to output one selected from the 2^{N} reference voltages VR[0], VR[1], . . . , VR[2^{N}-2], and VR[2^{N}−1] as the reference voltage VR_SEL.

The reference voltage generator 320 may control the plurality of switches SW of the DAC 610 by additionally using an inverted control signal SELB[(N−1):0] of the reference voltage control signal SEL[(N−1):0] in addition to the N-bit reference voltage control signal SEL[(N−1):0] input from the circuit controller 350. In this case, when the N-bit reference voltage control signal SEL[(N−1):0] is input from the circuit controller 350, the reference voltage generator 320 may generate an inverted control signal SELB[(N−1):0] which is inverted from the reference voltage control signal SEL[(N−1):0]. For example, when the reference voltage control signal SEL[(N−1):0] of “1000” is input from the circuit controller 350, the reference voltage generator 320 may generate an inverted reference voltage control signal SEL[(N−1):0] of “0111”, which is inverted from the reference voltage control signal SELB[(N−1):0].

In the DAC 610, the operation of the plurality of switches SW may be controlled according to the reference voltage control signal SEL[(N−1):0] and the inverted control signal SELB[(N−1):0]. The plurality of switches SW may include first switches SW1, the operation of which is controlled by the reference voltage control signal SEL[(N−1):0], and second switches SW2, the operation of which is controlled by the inversion control signal SELB[(N−1):0].

The patterned resistance detection circuit 210 according to one embodiment of the present invention is characterized in that it detects a voltage V_Panel by applying a reference current to the patterned resistance R_Panel, and compares the detected voltage V_Panel to the reference voltage VR_SEL. In contrast to the patterned resistance detection circuit 210 according to one embodiment of the present invention, a method of comparing a patterned resistance value and a variable resistance value has the problem that it requires a large area to be allocated to the resistor in order to reduce the deviation of the resistance value and it also requires a large area to be allocated to the switch in order to reduce the resistance value of the variable switch. In addition, the method of comparing the patterned resistance value and the variable resistance value has another problem that it has a reduced detection accuracy because the amount of change in the resistance value of the internal resistor and the resistance value of the variable switch exceeds 20% due to the temperature change.

The patterned resistance detection circuit 210 according to one embodiment of the present invention may remove the internal resistor and the variable switch SW, which occupy large areas, by using the reference current IREF instead of the variable resistance value. Accordingly, the patterned resistance detection circuit 210 according to one embodiment of the present invention may reduce the area.

Further, the patterned resistance detection circuit 210 according to one embodiment of the present invention may use a reference current and a reference voltage having a very small degree of change due to temperature, thereby maintaining high detection accuracy even when the temperature changes.

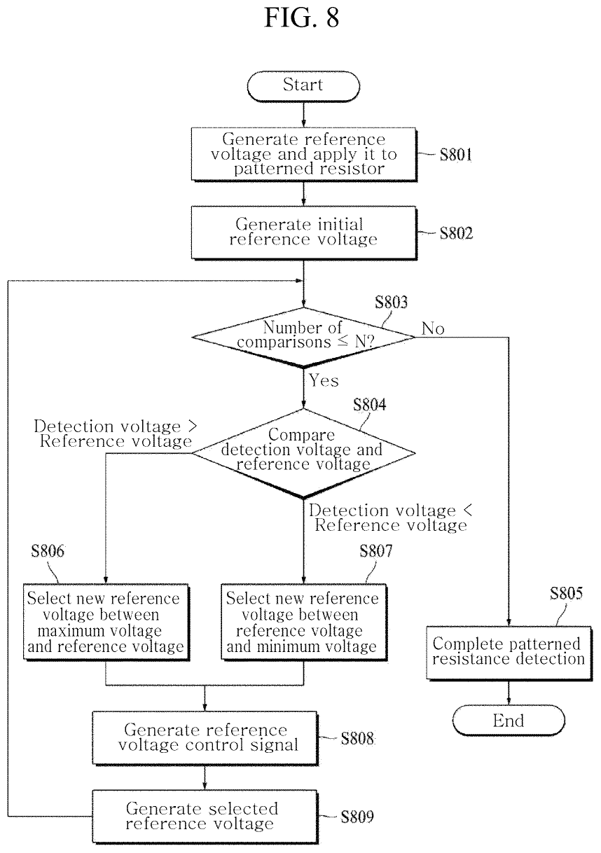

FIG. 8 is a flowchart illustrating a patterned resistance detection method of a display panel according to one embodiment of the present invention.

Referring to FIG. 8, first, the patterned resistance detection circuit 210 generates a reference current and applies the reference current to the patterned resistance R_Panel (S801).

For example, when an enable control signal becomes a high level, the patterned resistance detection circuit 210 may start the patterned resistance detection while the first switch SW_R connected to the first pad P1 of the display panel 110 and the second switch SW_L connected to the second pad P2 of the display panel 110 are turned on. The patterned resistance detection circuit 210 may generate a reference current and apply the generated reference current to the patterned resistance R_Panel via the first pad P1 of the display panel 110.

Next, the patterned resistance detection circuit 210 generates an initial reference voltage VR_SEL (S802). The patterned resistance detection circuit 210 may select one of a plurality of voltages as the initial reference voltage VR_SEL. The patterned resistance detection circuit 210 may generate a reference voltage control signal for generating the initial reference voltage VR_SEL. The patterned resistance detection circuit 210 may generate the initial reference voltage VR_SEL selected according to the reference voltage control signal.

In one embodiment, the patterned resistance detection circuit 210 may select a voltage having a median value from among the voltages between the maximum voltage and the minimum voltage as the initial reference voltage VR_SEL.

In another embodiment, the patterned resistance detection circuit 210 may select the maximum voltage as the initial reference voltage VR_SEL.

In another embodiment, the patterned resistance detection circuit 210 may select the minimum voltage as the initial reference voltage VR_SEL.

After that, when the number of comparisons between the detection voltage V_Panel and the reference voltage VR_SEL is greater than or equal to a preset value, the patterned resistance detection circuit 210 completes the detection of the patterned resistance (S803 and S805).

When the number of comparisons between the detection voltage V_Panel and the reference voltage VR_SEL is equal to or greater than the preset value, the patterned resistance detection circuit 210 may stop the detection operation of the patterned resistance R_Panel and provide a finally selected reference voltage or a final reference voltage control signal to the user. The user may determine the patterned resistance R_Panel of the display panel 110 based on the finally selected reference voltage or the final reference voltage control signal.

Additionally, the patterned resistance detection circuit 210 may determine a fault of the display panel 110 based on the finally selected reference voltage or the final reference voltage control signal.

Next, the patterned resistance detection circuit 210 compares the magnitudes of the detection voltage V_Panel and the reference voltage VR_SEL (S804).

In the patterned resistance detection circuit 210, each of the detection voltage V_Panel and the reference voltage VR_SEL is input to the comparator 330, and the value output from the comparator 330 may be obtained as a voltage comparison result. When the detection voltage V_Panel is greater than the reference voltage VR_SEL, the comparator 330 may output a high-level signal as a result of a voltage comparison between the detection voltage V_Panel and the reference voltage VR_SEL. On the other hand, when the detection voltage V_Panel is less than the reference voltage VR_SEL, the comparator 330 may output a low-level signal as a voltage comparison result between the detection voltage V_Panel and the reference voltage VR_SEL.

In one embodiment, the comparator 330 may compare the magnitudes of the detection voltage V_Panel and the reference voltage VR_SEL based on a clock signal Clk. The clock signal Clk may be input from the timing controller 116.

Next, when the detection voltage V_Panel is greater than the reference voltage VR_SEL, the patterned resistance detection circuit 210 selects a new reference voltage between the maximum voltage and the reference voltage (S806).

The patterned resistance detection circuit 210 may select one of the voltages between the minimum and maximum voltages of the expected range as the new reference voltage VR_SEL.

In one embodiment, the patterned resistance detection circuit 210 may select one of the 2^{N} voltages as the reference voltage. When the detection voltage V_Panel is greater than the reference voltage VR_SEL, the patterned resistance detection circuit 210 may change the minimum voltage of the expected range to a current reference voltage. Then, the patterned resistance detection circuit 210 may select one of the voltages between the maximum and minimum voltages of the expected range from among the 2^{N} voltages as the new reference voltage VR_SEL. In other words, when the detection voltage V_Panel is greater than the reference voltage VR_SEL, the patterned resistance detection circuit 210 may select a voltage greater than a current reference voltage from among the 2^{N} voltages as the new reference voltage.

In one embodiment, when the detection voltage V_Panel is greater than the reference voltage VR_SEL, the patterned resistance detection circuit 210 may change the minimum voltage of the expected range to a current reference voltage, and select a voltage having a median value among voltages between the maximum voltage and the minimum voltage of the expected range among the 2^{N} voltages as the new reference voltage.

Next, when the detection voltage V_Panel is less than the reference voltage VR_SEL, the patterned resistance detection circuit 210 selects a new reference voltage between the minimum voltage and the reference voltage (S807).

The patterned resistance detection circuit 210 may select one of the voltages between the minimum and maximum voltages of the expected range as the new reference voltage VR_SEL.

In one embodiment, the patterned resistance detection circuit 210 may select one of the 2^{N} voltages as the reference voltage. When the detection voltage V_Panel is less than the reference voltage VR_SEL, the patterned resistance detection circuit 210 may change the maximum voltage of the expected range to the current reference voltage. Then, the patterned resistance detection circuit 210 may select one of the voltages between the minimum voltage of the expected range and the current reference voltage from among the 2^{N} voltages as the new reference voltage VR_SEL. In other words, when the detection voltage V_Panel is smaller than the reference voltage VR_SEL, the patterned resistance detection circuit 210 may select a voltage smaller than the current reference voltage from among the 2^{N} voltages as the new reference voltage.

In one embodiment, when the detection voltage V_Panel is smaller than the reference voltage VR_SEL, the patterned resistance detection circuit 210 may change the maximum voltage of the expected range to a current reference voltage, and select a voltage having a median value among voltages between the minimum voltage and the maximum voltage of the expected range among the 2^{N} voltages as the new reference voltage.

Next, the patterned resistance detection circuit 210 generates a reference voltage control signal (S808).

In one embodiment, the patterned resistance detection circuit 210 may generate an N-bit reference voltage control signal for generating the selected reference voltage. In this case, the N-bit reference voltage control signal may contain 2^{N} reference voltage control signals having different values. The 2^{N} reference voltage control signals may correspond to 2^{N} voltages, respectively, and the 2^{N} voltages may correspond to the magnitudes of the 2^{N} patterned resistance R_Panel, respectively.

In one embodiment, the patterned resistance detection circuit 210 may generate an N-bit reference voltage control signal by changing a value of some bits of the N bits based on the voltage comparison result.

Specifically, when the detection voltage V_Panel is greater than the reference voltage VR_SEL, the patterned resistance detection circuit 210 may generate the reference voltage control signal by maintaining the value of the bit of the (i−1)th digit of the most significant bit and changing the value of the bit of the (i)th digit of 0 to 1. Where i is the number of comparisons between the detection voltage V_Panel and the reference voltage VR_SEL.

On the other hand, when the detection voltage V_Panel is less than the reference voltage VR_SEL, the patterned resistance detection circuit 210 may generate the reference voltage control signal by changing the value of the bit of the (i−1)th digit of the most significant bit to 0 and changing the value of the bit of the (i)th digit from 0 to 1.

Next, the patterned resistance detection circuit 210 generates the selected reference voltage VR_SEL (S809).

The patterned resistance detection circuit 210 may generate the selected reference voltage VR_SEL using a plurality of resistors connected in series and a plurality of switches connected to the nodes between the plurality of resistors. Specifically, the patterned resistance detection circuit 210 may control a plurality of switches according to the reference voltage control signal to cause the reference voltage VR_SEL selected from the 2^{N} reference voltages to be input to the comparator 330.

The patterned resistance detection circuit 210 may repeat S803 through S809 until the patterned resistance detection is complete.

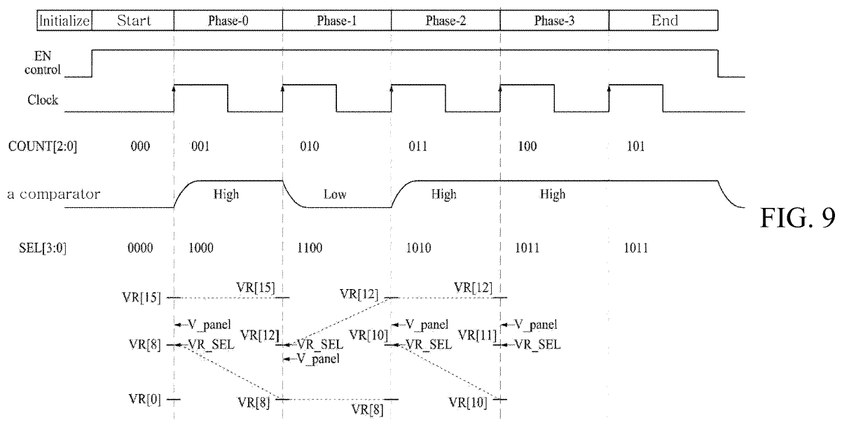

FIG. 9 is a diagram illustrating an example of a process in which a patterned resistance is detected by a patterned resistance detection circuit.

In FIG. 9, it is assumed that the resolution is 4 bits. In other words, the patterned resistance detection circuit 210 assumes that one of the 24 voltages is generated as the reference voltage VR_SEL by the 4-bit reference voltage control signal SEL[3:0].

The patterned resistance detection circuit 210 may start the patterned resistance detection by an enable control signal (EN control). For example, when the enable control signal becomes a high level, the patterned resistance detection circuit 210 may start the patterned resistance detection while the first switch SW_R connected to the first pad P1 of the display panel 110 and the second switch SW_L connected to the second pad P2 of the display panel 110 are turned on. The patterned resistance detection circuit 210 may generate a reference current and apply the generated reference current to the patterned resistance R_Panel via the first pad P1 of the display panel 110.

The patterned resistance detection circuit 210 may initialize the reference voltage control signal SEL[3:0] to “0000”, and initialize the number of comparisons COUNT[2:0] between the detection voltage V_Panel and the reference voltage VR_SEL to “000”.

The patterned resistance detection circuit 210 changes the number of comparisons COUNT[2:0] between the detection voltage V_Panel and the reference voltage VR_SEL to “001”, and may perform comparisons between the detection voltage V_Panel and the reference voltage VR_SEL because the number of comparisons COUNT[2:0] is less than 4, which is a preset value.

The patterned resistance detection circuit 210 may change the reference voltage control signal SEL[3:0] to “1000”, and thus the reference voltage VR_SEL may be generated according to the reference voltage control signal SEL[3:0] of “1000”. For example, when the reference voltage control signal SEL[3:0] and the pattern resistance R_Panel have the relationship as shown in Table 1, the patterned resistance detection circuit 210 may generate the reference voltage VR_SEL corresponding to the patterned resistance R_Panel having the magnitude of “9” according to the reference voltage control signal SEL[3:0] of “1000”.

The patterned resistance detection circuit 210 may compare the magnitudes of the detection voltage V_Panel detected by the reference current applied to the patterned resistance R_Panel and the reference voltage VR_SEL according to the clock signal Clk by using the comparator 330.

As shown in FIG. 9, the comparator 330 of the patterned resistance detection circuit 210 may output a high level signal as a result of a voltage comparison between the detection voltage V_Panel and the reference voltage VR_SEL during the first clock cycle Phase-0, because the detection voltage V_Panel is greater than the reference voltage VR_SEL.

Then, the patterned resistance detection circuit 210 changes the number of comparisons COUNT[2:0] between the detection voltage V_Panel and the reference voltage VR_SEL to “010”, and may perform comparisons between the detection voltage V_Panel and the reference voltage VR_SEL because the number of comparisons COUNT[2:0] is less than 4, which is a preset value.

The patterned resistance detection circuit 210 may generate the reference voltage control signal SEL[3:0] by maintaining the value of the bit of the most significant bit digit at 1 and changing the value of the bit of the first digit of the most significant bit from 0 to 1. As a result, the patterned resistance detection circuit 210 may generate the reference voltage control signal SEL[3:0] of “1100”, and the reference voltage VR_SEL may be changed according to the reference voltage control signal SEL[3:0] of “1100”. For example, the patterned resistance detection circuit 210 may generate the reference voltage VR_SEL corresponding to the patterned resistance R_Panel having a magnitude of “13” according to the reference voltage control signal SEL[3:0] of “1100”.

The patterned resistance detection circuit 210 may compare the magnitudes of the detection voltage V_Panel detected by the reference current applied to the patterned resistance R_Panel and the reference voltage VR_SEL according to the clock signal Clk by using the comparator 330.

The comparator 330 of the patterned resistance detection circuit 210 may output a low level signal as a result of a voltage comparison between the detection voltage V_Panel and the reference voltage VR_SEL during the second clock cycle Phase-1, because the detection voltage V_Panel is less than the reference voltage VR_SEL.

Then, the patterned resistance detection circuit 210 changes the number of comparisons COUNT[2:0] between the detection voltage V_Panel and the reference voltage VR_SEL to “011”, and may perform comparisons between the detection voltage V_Panel and the reference voltage VR_SEL because the number of comparisons COUNT[2:0] is less than 4, which is a preset value.

The patterned resistance detection circuit 210 may generate the reference voltage control signal SEL[3:0] by changing the value of the bit of the first digit from the most significant bit to 0 and changing the value of the bit of the second digit from the most significant bit to 1 from 0. As a result, the patterned resistance detection circuit 210 may generate the reference voltage control signal SEL[3:0] of “1010”, and the reference voltage VR_SEL may be changed according to the reference voltage control signal SEL[3:0] of “1010”. For example, the patterned resistance detection circuit 210 may generate the reference voltage VR_SEL corresponding to the patterned resistance R_Panel having a magnitude of “11” according to the reference voltage control signal SEL[3:0] of “1010”.

The patterned resistance detection circuit 210 may compare the magnitudes of the detection voltage V_Panel detected by the reference current applied to the patterned resistance R_Panel and the reference voltage VR_SEL according to the clock signal Clk by using the comparator 330.

The comparator 330 of the patterned resistance detection circuit 210 may output a high level signal as a result of a voltage comparison between the detection voltage V_Panel and the reference voltage VR_SEL during the third clock cycle Phase-2, because the detection voltage V_Panel is greater than the reference voltage VR_SEL.

Then, the patterned resistance detection circuit 210 changes the number of comparisons COUNT[2:0] between the detection voltage V_Panel and the reference voltage VR_SEL to “100”, and may perform comparisons between the detection voltage V_Panel and the reference voltage VR_SEL because the number of comparisons COUNT[2:0] is less than 4, which is a preset value.

The patterned resistance detection circuit 210 may generate a reference voltage control signal SEL[3:0] by maintaining the value of the bit of the second digit from the most significant bit at 1 and changing the value of the bit of the third digit from the most significant bit from 0 to 1. As a result, the patterned resistance detection circuit 210 may generate the reference voltage control signal SEL[3:0] of “1011”, and the reference voltage VR_SEL may be changed according to the reference voltage control signal SEL[3:0] of “1011”. For example, the patterned resistance detection circuit 210 may generate the reference voltage VR_SEL corresponding to the patterned resistance R_Panel having a magnitude of “12” according to the reference voltage control signal SEL[3:0] of “1011”.

The patterned resistance detection circuit 210 may compare the magnitudes of the detection voltage V_Panel detected by the reference current applied to the patterned resistance R_Panel and the reference voltage VR_SEL according to the clock signal Clk by using the comparator 330.

The comparator 330 of the patterned resistance detection circuit 210 may output a high level signal as a result of a voltage comparison between the detection voltage V_Panel and the reference voltage VR_SEL during the fourth clock cycle Phase-3, because the detection voltage V_Panel is greater than the reference voltage VR_SEL.

Then, the patterned resistance detection circuit 210 changes the number of comparisons COUNT[2:0] between the detection voltage V_Panel and the reference voltage VR_SEL to “101”, and may complete the patterned resistance detection because the number of comparisons COUNT[2:0] is equal to 4, which is a preset value.

The patterned resistance detection circuit 210 may provide a final reference voltage control signal to the user. The user may determine that the patterned resistance R_Panel of the display panel 110 is 12 k (2 based on the final reference voltage control signal “1011”.

Those skilled in the art to which the present invention belongs will understand that the present invention described above may be implemented in other specific forms without changing its technical idea or essential features.

In addition, the methods described herein may be implemented, at least in part, using one or more computer programs or components. The component may be provided as a set of computer instructions on a computer-readable medium including volatile and non-volatile memory or a machine-readable medium. The above instructions may be provided as software or firmware and may be implemented, in whole or in part, in hardware configurations such as ASICs, FPGAs, DSPs, or other similar devices. The above instructions may be configured to be executed by one or more processors or other hardware configurations, which, when executing the above set of computer instructions, perform or cause to be performed all or a portion of the methods and procedures disclosed herein.

The present specification described above is not limited to the foregoing embodiments and the accompanying drawings, and it will be apparent to a person skilled in the art to which the present specification belongs that various substitutions, modifications, and changes may be made within the scope without departing from the technical spirit of the present specification. Therefore, the scope of the present specification is represented by the following claims, and it should be construed that all changes or modifications derived from the meaning and scope of the claims and the equivalent concept thereof are included within the scope of the present specification.

### MODE OF PRACTICING THE INVENTION

A variety of modes for practicing the present invention have been described in the preceding subheadings, Best Modes for Carrying Out the Invention.

### INDUSTRIAL APPLICABILITY

The present invention is applicable to any type of display devices (e.g., LCD, LED, OLED, etc.) and is therefore industrially available.

1. A patterned resistance detection circuit comprising:
a current source generator configured to generate a reference current and applies the reference current to a patterned resistance;
a reference voltage generator configuration to generate a reference voltage;
a comparator configuration configured to compare a magnitude of a detection voltage detected by the reference current applied to the patterned resistance to a magnitude of the reference voltage and output a voltage comparison result; and
a circuit controller configured to output a reference voltage control signal for controlling the reference voltage generator according to the voltage comparison result.

2. The patterned resistance detection circuit of claim 1, wherein the current source generator includes:
a current source connected to a first power source;
a first transistor including a first drain electrode connected to the current source, a first gate electrode connected to the first drain electrode, and a first source electrode connected to a second power source; and
a second transistor including a second drain electrode connected to the patterned resistance, a second gate electrode connected to the first gate electrode of the first transistor, and a second source electrode connected to the second power source.

3. The patterned resistance detection circuit of claim 2, wherein a first reference current flows through the first transistor, and a second reference current copied from the first reference current flows through the second transistor.

4. The patterned resistance detection circuit of claim 2, wherein the first power source is a low potential voltage and the second power source is a high potential voltage.

5. The patterned resistance detection circuit of claim 2, wherein the second drain electrode of the second transistor is connected to the first power source via the patterned resistance.

6. The patterned resistance detection circuit of claim 2, wherein the current source generator further includes:
a bias transistor configured to supply a constant bias current to the first transistor.

7. The patterned resistance detection circuit of claim 2, wherein the current source generator further includes:
a channel length modulation prevention circuit configured to copy a first drain voltage of the first transistor to a second drain voltage of the second transistor.

8. The patterned resistance detection circuit of claim 7, wherein the channel length modulation prevention circuit includes:
a differential amplifier configured to amplify a difference between the first drain voltage of the first transistor and the second drain voltage of the second transistor; and
a third transistor including a third drain electrode connected to the patterned resistance, a third gate electrode connected to the differential amplifier, and a third source electrode connected to the second drain electrode of the second transistor.

9. The patterned resistance detection circuit of claim 1, wherein the circuit controller is configured to:
select one of the 2^{N} voltages as the reference voltage based on the voltage comparison result; generate an N-bit reference voltage control signal for generating a selected reference voltage; and output the N-bit reference voltage control signal to the reference voltage generator.

10. The patterned resistance detection circuit of claim 9, wherein the circuit controller is configured to:
select one of the voltages less than a current reference voltage from among the 2^{N} voltages as a new reference voltage when the reference voltage is greater than the detection voltage; and
select one of the voltages greater than the current reference voltage from among the 2^{N} voltages as a new reference voltage when the reference voltage is less than the detection voltage.
